(19) United States
(12) Patent Application Publication
(10) Pub. No.: US 2008/0273370 A1
(43) Pub. Date: Nov. 6, 2008

(54) Integrated Circuit, Method of Operating an Integrated Circuit, Memory Cell Array, and Memory Module

(76) Inventors: Jan Keller, Fontainebleau (FR); Ralf Symanczyk, Tuntenhausen (DE)

Correspondence Address: SLATER & MATSIL, L.L.P., 17950 PRESTON ROAD, SUITE 1000, DALLAS, TX, 75252, US

(21) Appl. No.: 11/743,595

(22) Filed: May 2, 2007

(51) Int. Cl. G11C 11/08; H01L 45/00

(52) U.S. Cl. 365/148; 257/4; 365/189.04; 257/E45.003

(57) ABSTRACT

According to one embodiment of the present invention, an integrated circuit includes a memory cell that includes at least two resistivity changing layers being stacked above each other, each resistivity changing layer serving as a separate data storage layer and having individual data storing properties.

### BRIEF DESCRIPTION OF THE DRAWINGS

For a more complete understanding of exemplary embodiments of the present invention, reference is now made to the following description taken in conjunction with the accompanying drawings, in which:

FIG. 1A shows a schematic cross-sectional view of a solid electrolyte memory cell set to a first memory state;

FIG. 1B shows a schematic cross-sectional view of a solid electrolyte memory cell set to a second memory state;

FIG. 2 shows a schematic cross-sectional view of a solid electrolyte memory cell according to one embodiment of the present invention;

FIG. 3 shows a schematic cross-sectional view of a solid electrolyte memory cell according to one embodiment of the present invention;

FIG. 4 shows the solid electrolyte memory cell of FIG. 3 in a first memory state;

FIG. 5 shows the solid electrolyte memory cell of FIG. 3 in a second memory state;

FIG. 6 shows solid electrolyte memory cell of FIG. 3 in a third memory state;

FIG. 7 shows the solid electrolyte memory cell in a fourth memory state;

FIG. 8 shows a schematic flow chart of a method of operating a solid electrolyte memory cell according to one embodiment of the present invention;

FIG. 9 shows a schematic flow chart of a method of operating a solid electrolyte memory cell according to one embodiment of the present invention;

FIG. 10 shows a schematic flow chart of a method of operating a solid electrolyte memory cell according to one embodiment of the present invention;

FIG. 11 shows a schematic flow chart of a method of operating a solid electrolyte memory cell according to one embodiment of the present invention;

FIG. 12 shows a schematic flow chart of a method of operating a solid electrolyte memory cell according to one embodiment of the present invention;

FIG. 13A shows a memory module according to one embodiment of the present invention;

FIG. 13B shows a memory module according to one embodiment of the present invention;

FIG. 14 shows a cross-sectional view of a phase changing memory cell;

FIG. 15 shows a schematic drawing of a memory device including resistivity changing memory cells;

FIG. 16A shows a cross-sectional view of a carbon memory cell set to a first switching state;

FIG. 16B shows a cross-sectional view of a carbon memory cell set to a second switching state;

FIG. 17A shows a schematic drawing of a resistivity changing memory cell; and

FIG. 17B shows a schematic drawing of a resistivity changing memory cell.

### DETAILED DESCRIPTION OF ILLUSTRATIVE EMBODIMENTS

For sake of simplicity, it is assumed in the following description that the memory device is a solid electrolyte memory device, that the resistivity changing memory cell is a solid electrolyte memory cell, and that the resistivity changing layers are solid electrolyte layers. However, the present invention is also applicable to other types of resistivity changing memory devices like magneto-resistive memory devices (MRAM devices), phase changing memory devices (PCRAM devices), and organic memory devices (ORAM devices).

According to one embodiment of the present invention, an integrated circuit includes a solid electrolyte memory cell including at least two solid electrolyte layers being stacked above each other, each solid electrolyte layer serving as a separate data storage layer and having individual data storing properties.

According to one embodiment of the present invention, each solid electrolyte layer has individual data retention properties or data writing properties (data retention properties and data writing properties are examples of “data storing properties”; the term “data storing properties” also includes further properties like data reading properties, tolerance properties, and the like).

According to one embodiment of the present invention, a solid electrolyte memory cell includes at least two solid electrolyte layers being stacked above each other, each solid electrolyte layer serving as a separate data storage layer and having individual data retention properties or data writing properties.

The stack may comprise an arbitrary number of solid electrolyte layers. Each solid electrolyte layer may show individual data writing properties and/or data retention properties. However, the data writing properties and/or data retention properties of some solid electrolyte layers may also be the same.

According to one embodiment of the present invention, the solid electrolyte layers are grouped into pairs, the solid electrolyte layers of a pair being disposed adjacent to each other and being electrically connected by an electrical connection.

According to one embodiment of the present invention, the electrical connection is a common electrode layer. In other words, the solid electrolyte memory cell comprises a stack in which solid electrolyte layers and electrode layers (electrical connections) alternate with each other. Of course, the stack may comprise further layers of a different type (e.g., adaptation layers) which are inserted between the solid electrolyte layers and the electrode layers.

According to one embodiment of the present invention, a solid electrolyte memory cell includes a first electrode layer, a second electrode layer and a third electrode layer, the second electrode layer being provided between the first electrode layer and the third electrode layer. The solid electrolyte memory cell further includes a first solid electrolyte layer being provided between the first electrode layer and the second electrode layer, and a second solid electrolyte layer being provided between the second electrode layer and the third electrode layer.

The memory cell according to this embodiment has two different data storing areas: the first solid electrolyte layer and the second solid electrolyte layer. The provision of two data storing areas within one memory cell enables the memory density of a memory cell array to increase using such memory cells.

Further, it is possible to broaden the range of use of such memory cells: according to one embodiment of the present invention, one of the first and second solid electrolyte layers (for example, the first solid electrolyte layer) has a high memory state switching speed, whereas the other solid electrolyte layer (for example, the second solid electrolyte layer) has a high data retention. To be more general, each of the first and second solid electrolyte layers can independently be optimised for individual requirements.

According to one embodiment of the present invention, the first solid electrolyte layer includes GeS, AgS or a combination of these materials or consists of GeS, AgS or a combination of these materials. The invention, however, is not restricted to these materials.

According to one embodiment of the present invention, the second solid electrolyte layer includes GeSe, AgSe or a combination of these materials, or consists of GeSe, AgSe or a combination of these materials. The invention, however, is not restricted to these materials and other possible materials are WOₓ and NiOₓ.

According to one embodiment of the present invention, the first electrode includes inert material or consists of inert material.

According to one embodiment of the present invention, the second electrode includes inert material and reactive material.

According to one embodiment of the present invention, the third electrode includes reactive material or consists of reactive material.

According to one embodiment of the present invention, the second electrode includes a first portion arranged on the first solid electrolyte layer, and a second portion arranged on the first portion, the first portion including reactive material or consisting of reactive material, and the second portion including inert material or consisting of inert material.

According to one embodiment of the present invention, the inert material includes Ti, W, TiN, WN, Ta, TaN or a combination of these materials, or consists of Ti, W, TiN, WN, Ta, TaN or a combination of these materials. However, the present invention is not restricted to these materials.

According to one embodiment of the present invention, the reactive material includes Cu, Ag, AgS or other metallic material, or consists of Cu, Ag, AgS or other metallic material.

According to one embodiment of the present invention, the thickness of the first electrode layer or of the second portion of the second electrode layer ranges from 2 nm to 10 μm or ranges from 30 nm to 1 μm or ranges from 50 nm to 200 nm or is 100 nm.

According to one embodiment of the present invention, the thickness of the first solid electrolyte layer or of the second solid electrolyte layer ranges from 2 nm to 2 μm or ranges from 10 nm to 1 μm or ranges from 30 nm to 150 nm or is 50 nm.

According to one embodiment of the present invention, the thickness of the first portion of the second electrode layer or of the third electrode layer is less than 1 μm or is less than 100 nm or ranges from 10 nm to 70 nm or ranges from 25 nm to 40 nm.

According to one embodiment of the present invention, each of the first electrode layer, the second electrode layer or the third electrode layer is individually addressable via respective electrode layer terminals.

According to one embodiment of the present invention, the first electrode layer is the bottom electrode layer of the first solid electrolyte layer, the second electrode layer is the top electrode layer of the first solid electrolyte layer and the bottom electrode layer of the second solid electrolyte layer, and the third electrode layer is the top electrode layer of the second solid electrolyte layer.

According to one embodiment of the present invention, a memory module comprising at least one integrated circuit according to one embodiment of the present invention and/or memory cell according to one embodiment of the present invention is provided. According to one embodiment of the present invention, the memory module is stackable.

According to one embodiment of the present invention, a memory cell array including a plurality of memory cells is provided, wherein at least some of the memory cells include at least two solid electrolyte layers being stacked above each other, each solid electrolyte layer serving as a separate data storage layer and having individual data storing properties.

According to one embodiment of the present invention, each memory cell of the memory cell array includes: a first electrode layer, a second electrode layer, and a third electrode layer, the second electrode layer being provided between the first electrode layer and the third electrode layer; a first solid electrolyte layer being provided between the first electrode layer and the second electrode layer; and a second solid electrolyte layer being provided between the second electrode layer and the third electrode layer.

All embodiments of the solid electrolyte memory cell according to the present invention discussed above may also be applied to the embodiments of the memory cell array according to the present invention.

According to one embodiment of the present invention, a method of operating an integrated circuit including a solid electrolyte memory cell is provided, the memory cell including: a first electrode layer, a second electrode layer, and a third electrode layer, the second electrode layer being provided between the first electrode layer and the third electrode layer; a first solid electrolyte layer being provided between the first electrode layer and the second electrode layer; and a second solid electrolyte layer being provided between the second electrode layer and the third electrode layer. The method includes applying a voltage between the first electrode layer and the third electrode layer, the voltage being chosen such that the memory state of the first solid electrolyte layer is copied to the second solid electrolyte layer.

According to one embodiment of the present invention, a method of operating a solid electrolyte memory cell is provided, the memory cell including: a first electrode layer, a second electrode layer, and a third electrode layer, the second electrode layer being provided between the first electrode layer and the third electrode layer; a first solid electrolyte layer being provided between the first electrode layer and the second electrode layer; and a second solid electrolyte layer being provided between the second electrode layer and the third electrode layer. The method includes applying a voltage between the first electrode layer and the third electrode layer, the voltage being chosen such that the memory state of the first solid electrolyte layer is copied to the second solid electrolyte layer.

According to one embodiment of the present invention, the first solid electrolyte layer enables the storage of data with high data storage speed, and the second solid electrolyte layer enables the storage of data with high data retention (or vice versa). For example, the first solid electrolyte layer may have a higher memory state switching speed than the second solid electrolyte layer, and/or the second solid electrolyte layer may have a higher data retention than the first solid electrolyte layer.

According to one embodiment of the present invention, the second electrode layer is kept in a floating state during the application of the voltage between the first electrode and the third electrode.

According to one embodiment of the present invention, the following relations are fulfilled during application of the voltage between the first electrode layer and the third electrode layer: Vₛₜₒᵣₑ>VthON2, and Vₛₜₒᵣₑ<(VthON1+VthON2).

In this formula, Vₛₜₒᵣₑ is the voltage applied between the first electrode and the third electrode, VthON1 is the memory state programming threshold voltage of the first solid electrolyte layer and VthON2 is the memory state programming threshold voltage of the second solid electrolyte layer. It is to be understood that the present invention is not restricted to the voltage relations mentioned above. According to one embodiment of the present invention, it is assumed that VthON1 refers to a voltage directly applied across the first solid electrolyte layer, i.e., applied between the first electrode and the second electrode, and it is assumed that VthON2 refers to a voltage directly applied across the second solid electrolyte layer, i.e., applied between the second electrode and the third electrode.

According to one embodiment of the present invention, the memory state of the second solid electrolyte layer is set to a defined memory state before copying the memory state of the first solid electrolyte layer to the second solid electrolyte layer. For example, in order to set the second solid electrolyte layer to a defined memory state, the second solid electrolyte layer may be subjected to an erase operation which removes conductive paths formed within the second solid electrolyte layer. The second solid electrolyte layer may, for example, have a higher data retention than the first solid electrolyte layer.

According to one embodiment of the present invention, a voltage is applied between the first electrode layer and the third electrode layer, wherein the voltage is chosen such that the memory state of the second solid electrolyte layer is copied into the first solid electrolyte layer.

According to one embodiment of the present invention, the second electrode layer is kept in a floating state during application of the voltage between the first electrode and the third electrode when copying the memory state of the second solid electrolyte layer into the first solid electrolyte layer.

According to one embodiment of the present invention, wherein the following relations are fulfilled during application of the voltage between the first electrode layer and the third electrode layer when copying the memory state of the second solid electrolyte layer into the first solid electrolyte layer: Vₛₜₒᵣₑ>VthON1, and Vₛₜₒᵣₑ<(VthON1+VthON2), wherein Vₛₜₒᵣₑ is the voltage applied between the first electrode and the third electrode, VthON1 is the memory state programming threshold voltage of the first solid electrolyte layer, and VthON2 is the memory state programming threshold voltage of the second solid electrolyte layer. According to one embodiment of the present invention, it is assumed that VthON1 refers to a voltage directly applied across the first solid electrolyte layer, i.e., applied between the first electrode and the second electrode, and it is assumed that VthON2 refers to a voltage directly applied across the second solid electrolyte layer, i.e., applied between the second electrode and the third electrode.

According to one embodiment of the present invention, the memory state of the first solid electrolyte layer is set to a defined memory state before copying the memory state of the second solid electrolyte layer into the first solid electrolyte layer.

According to one embodiment of the present invention, a method of operating a solid electrolyte memory cell is provided. The memory cell includes a first electrode layer, a second electrode layer, and a third electrode layer, the second electrode layer being provided between the first electrode layer and the third electrode layer. A first solid electrolyte layer is provided between the first electrode layer and the second electrode layer. A second solid electrolyte layer is provided between the second electrode layer and the third electrode layer. The method includes simultaneously reading the memory states of the first solid electrolyte layer and the second solid electrolyte layer by applying a voltage between the first electrode layer and the third electrode layer and sensing a resulting current (or a resulting voltage signal) flowing through the first solid electrolyte layer and the second solid electrolyte layer. Alternatively, the memory states of the first solid electrolyte layer and the second solid electrolyte layer can be read out separately, e.g., by applying separate read voltages between the first electrode layer and the second electrode layer and between the second electrode layer and the third electrode layer.

According to one embodiment of the present invention, a method of operating an integrated circuit including a solid electrolyte memory cell is provided. The memory cell includes a first electrode layer, a second electrode layer, and a third electrode layer, the second electrode layer being provided between the first electrode layer and the third electrode layer. A first solid electrolyte layer is provided between the first electrode layer and the second electrode layer. A second solid electrolyte layer is provided between the second electrode layer and the third electrode layer. The method includes simultaneously (or sequentially) reading the memory states of the first solid electrolyte layer and the second solid electrolyte layer by applying a voltage between the first electrode layer and the third electrode layer and sensing a resulting current (or a resulting voltage signal) flowing through the first solid electrolyte layer and the second solid electrolyte layer.

All embodiments of the solid electrolyte memory cell according to the present invention may also be applied to the solid electrolyte memory cells used in the embodiments of the method according to the present invention.

According to one embodiment of the present invention, a method of fabricating a solid electrolyte memory cell is provided, including: providing a first electrode layer; providing a first solid electrolyte layer on the first electrode layer; providing a second electrode layer on the first solid electrolyte layer; providing a second solid electrolyte layer on the second electrode layer; and providing a third electrode layer on the second solid electrolyte layer.

According to one embodiment of the present invention, a computer program product is provided configured to perform, when being executed on a computing device or a digital signal processor, a method of operating a solid electrolyte memory cell or an integrated circuit comprising a memory cell. The memory cell includes: a first electrode layer, a second electrode layer, and a third electrode layer, the second electrode layer being provided between the first electrode layer and the third electrode layer; a first solid electrolyte layer being provided between the first electrode layer and the second electrode layer; and a second solid electrolyte layer being provided between the second electrode layer and the third electrode layer. The method includes applying a voltage between the first electrode layer and the third electrode layer, the voltage being chosen such that the memory state of the first solid electrolyte layer is copied to the second solid electrolyte layer. Alternatively and/or additionally, the method includes simultaneously or sequentially reading the memory states of the first solid electrolyte layer and the second solid electrolyte layer by applying a voltage between the first electrode layer and the third electrode layer and sensing the resulting current (or voltage) flowing through the first solid electrolyte layer and the second solid electrolyte layer.

According to the present invention, a data carrier is provided which stores a computer program product according to the present invention.

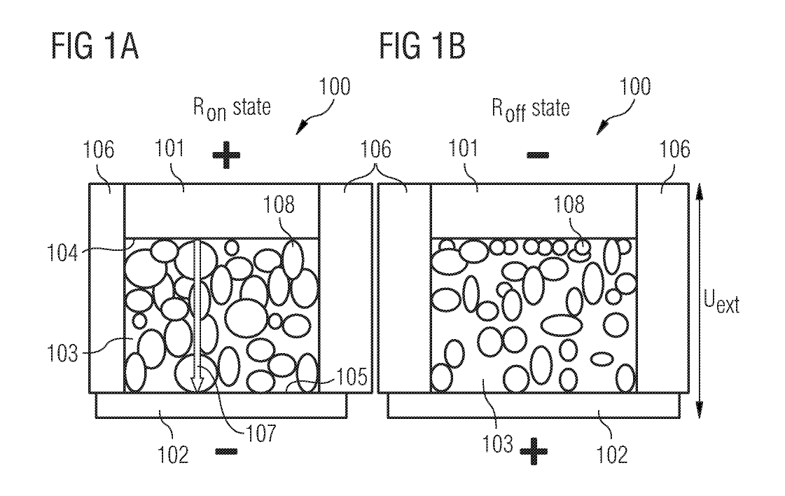

Since the embodiments of the present invention can be applied to programmable metallization cell devices (PMC) (e.g., solid electrolyte devices like CBRAM (conductive bridging random access memory) devices), in the following description, making reference to FIGS. 1A and 1B, a basic principle underlying embodiments of CBRAM devices will be explained.

As shown in FIG. 1A, a CBRAM cell 100 includes a first electrode 101 a second electrode 102, and a solid electrolyte block (in the following also referred to as ion conductor block) 103 which includes the active material and which is sandwiched between the first electrode 101 and the second electrode 102. This solid electrolyte block 103 can also be shared between a plurality of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂ or Si₃N₄. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 103 may, for example, range between 5 nm and 500 nm. The thickness of the first electrode 101 may, for example, range between 10 nm and 100 nm. The thickness of the second electrode 102 may, for example, range between 5 nm and 500 nm, between 15 nm to 150 nm, or between 25 nm and 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107. After having applied the voltage/inverse voltage, the memory cell 100 remains within the corresponding defined switching state even if the voltage/inverse voltage has been removed.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may, for example, represent “0”, whereas a low resistance represents “1”, or vice versa. The memory status detection may also be carried out using sensing voltages. Alternatively, a sensing voltage may be used in order to determine the current memory status of a CBRAM cell.

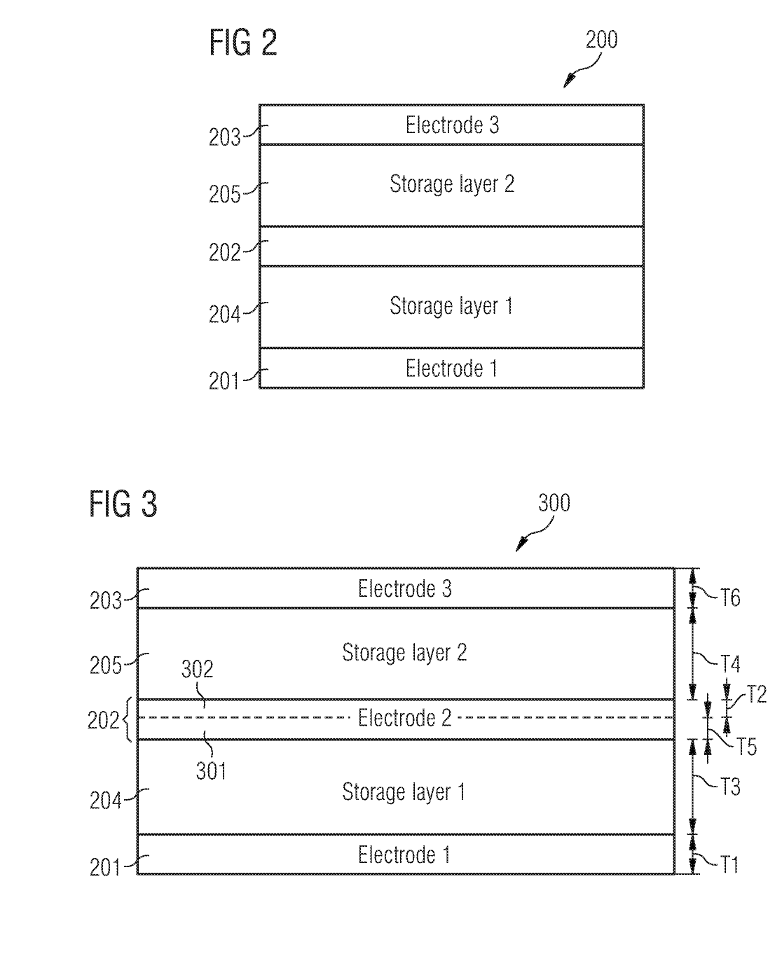

FIG. 2 shows one embodiment 200 of the solid electrolyte memory cell according to the present invention. The solid electrolyte memory cell 200 includes a first electrode layer 201, a second electrode layer 202 and a third electrode layer 203. The second electrode layer 202 is arranged between the first electrode layer 201 and the third electrode layer 203. The solid electrolyte memory cell 200 further includes a first solid electrolyte layer 204 arranged between the first electrode layer 201 and the second electrode layer 202, and a second solid electrolyte layer 205 arranged between the second electrode layer 202 and the third electrode layer 203.

The solid electrolyte memory cell 200 includes two data storing areas: the first solid electrolyte layer 204 and the second solid electrolyte layer 205. The characteristics of each data storing area can be adapted to individual requirements. For example, according to one embodiment of the present invention, the first solid electrolyte layer 204 is optimised for high programming speed, i.e., has a high memory state switching speed. In contrast, according to one embodiment of the present invention, the second solid electrolyte layer 205 is optimised for permanent data storage, i.e., data retention. As a consequence, as will become apparent further below, the flexibility of the solid electrolyte memory cell 200 is very high.

The present invention is not restricted to the optimization examples mentioned above. For example, it may also be possible to optimize the first solid electrolyte layer 204 with respect to low power consumption, and to optimise the second solid electrolyte layer 205 with respect to data reading reliability characteristics, etc.

In order to ensure a high memory state switching speed of the first solid electrolyte layer 204, the first solid electrolyte layer 204 may, for example, include GeS, AgS or a combination of these materials. Alternatively, the first solid electrolyte layer 204 may consist of GeS, AgS or a combination of these materials. It is to be understood that the present invention is not restricted to these examples.

In order to insure the high data retention of the second solid electrolyte layer 205, the second solid electrolyte layer 205 may comprise GeSe, AgSe or a combination of these materials. Alternatively, the second solid electrolyte layer 205 may consist of GeSe, AgSe or a combination of these materials. It is to be understood that the present invention is not restricted to these examples.

According to one embodiment of the present invention, the first electrode layer 201 includes inert material or consists of inert material, the second electrode layer 202 includes inert material and reactive material, and the third electrode layer 203 includes reactive material or consists of reactive material.

According to one embodiment of the present invention, the inert material may, for example, include titanium (Ti), tungsten (W), titanium nitride (TiN), tungsten nitride (WN), tantalum (Ta), tantalum nitride (TaN) or combinations of these materials. Alternatively, the inert material may consist of titanium, tungsten, titanium nitride, tungsten nitride, tantalum or a combination of these materials. It is to be understood that the present invention is not restricted to these examples.

According to one embodiment of the present invention, the reactive material may for example include copper (Cu), silver (Ag), silver sulfide (AgS) or other metallic material. Alternatively, the reactive material may consist of copper, silver or other metallic material. It is to be understood that the present invention is not restricted to these examples.

FIG. 3 shows an embodiment 300 of a solid electrolyte memory cell, the architecture of which being very similar to that of the solid electrolyte memory cell 200 shown in FIG. 2. The only difference is that the second electrode layer 202 is split into a first portion 301 arranged on the first solid electrolyte layer 204, and a second portion 302 arranged on the first portion 301. The first portion 301 includes reactive material or consists of reactive material, and the second portion 302 includes inert material or consists of inert material.

According to one embodiment of the present invention, the thickness TI of the first electrode layer 201 or the thickness T2 of the second portion 302 of the second electrode layer 202 ranges from 2 nm to 10 μm or ranges from 30 nm to 1 μm or ranges from 50 nm to 200 μm or is 100 nm.

According to one embodiment of the present invention, the thickness T3 of the first solid electrolyte layer 204 or the thickness T4 of the second solid electrolyte layer 205 ranges from 2 nm to 2 μm or ranges from 10 nm to 1 μm or ranges from 30 nm to 150 nm or is 50 nm.

According to one embodiment of the present invention, the thickness T5 of the first portion 301 of the second electrode layer 202 or the thickness T6 of the third electrode layer 203 is lower than 10 μm or is lower than 100 nm or ranges from 10 nm to 70 nm or ranges from 25 nm to 40 nm.

The threshold voltage for programming the first solid electrolyte layer 204 is VthON 1, and the threshold voltage for programming the second solid electrolyte layer 205 is VthON 2 (VthON 1 and VthON 2 refer to the process of forming conductive paths; corresponding threshold values for erasing conductive paths differ from VthON 1 and VthON 2).

The second portion 302 of the second electrode layer 202 (comprising or consisting of inert material) serves as a diffusion barrier for active metallic components of the first portion 301 of the second electrode layer 202 (for example, silver or copper).

According to one embodiment of the present invention, the first electrode layer 201, the second electrode layer 202 and the third electrode layer 203 are individually addressable via respective electrode layer terminals (not shown). This enables to individually program the memory state of each of the first and second solid electrolyte layers 204, 205 without influencing the memory state of the respective other of the first and second solid electrolyte layer 204, 205.

The solid electrolyte memory cells 200, 300 shown in FIGS. 2 and 3 have an architecture in which the first electrode layer 201 is the bottom electrode layer of the first solid electrolyte layer 204, the second electrode layer 202 is the top electrode layer of the first solid electrolyte layer 204 and the bottom electrode layer of the second solid electrolyte layer 205, and the third electrode layer 203 is the top electrode layer of the second solid electrolyte layer 205.

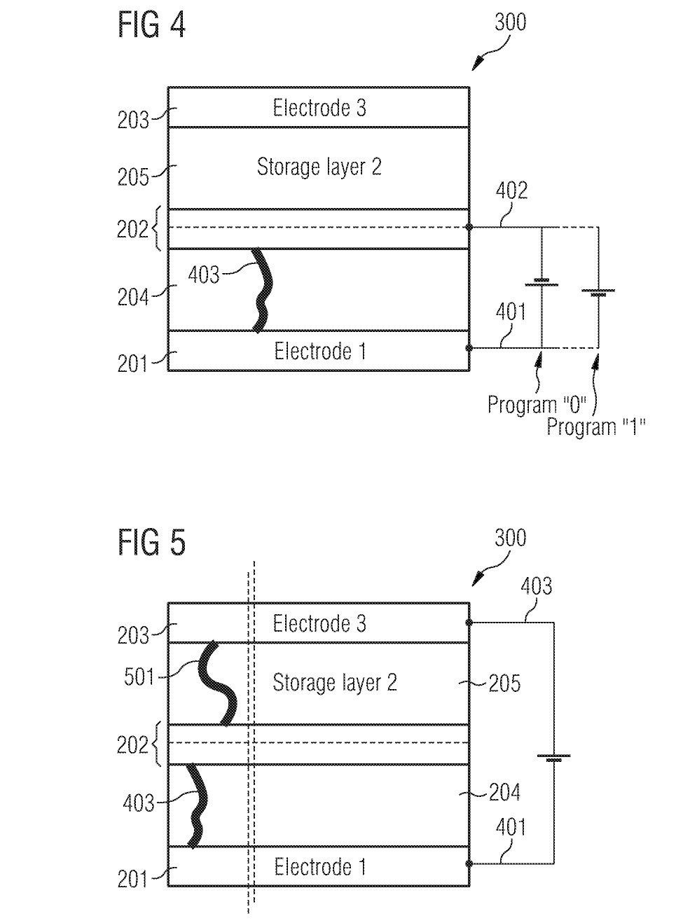

FIG. 4 shows one embodiment of operating the solid electrolyte memory cell 300 according to the present invention. In order to program the memory state of the first solid electrolyte layer 204, a programming voltage V_{prog} is applied between the first electrode layer 201 and the second electrode layer 202 using a first terminal 401 and a second terminal 402. The first terminal 401 is electrically connected to the first electrode layer 201, the second terminal 402 is electrically connected to the second electrode layer 202. If the voltage V_{prog} is larger than VthON1, a first conductive path 403 is formed between the first electrode layer 201 and the second electrode layer 202. If the sign of the voltage applied between the first electrode layer 201 and the second electrode layer 202 is inversed, the first conductive path 403 can be erased.

The memory state of the first solid electrolyte layer 204 can be read using the first and the second electrode layers 201, 202 or using the first electrode layer 201 and the third electrode layer 203 as sensing electrodes. The sensing process of the memory state can be carried out using a sensing current or a sensing voltage. According to an embodiment of the present invention, the absolute value of the voltage applied across the first solid electrolyte layer 204 during the reading process, V_{read}, has to be lower than the absolute value of the threshold voltage VthON1 applied across the first solid electrolyte layer 204 for forming conductive paths, and has also be lower than the absolute value of a corresponding erasing threshold voltage for erasing conductive paths.

If, as indicated above, the first solid electrolyte layer 204 is optimised with respect to memory state switching speed, the data retention of the first solid electrolyte layer 204 may not be very high. As a consequence, data stored within the first solid electrolyte layer 204 may be lost after a relatively short period of time. In order to avoid this, refresh cycles may be carried out during which the memory state of the first solid electrolyte layer 204 is reprogrammed. In this way, it is ensured that the memory state of the first solid electrolyte layer 204 is maintained in the long run. However, if the solid electrolyte memory device comprising the solid electrolyte memory cell 300 is switched off, no refresh cycles can be carried out which may result in a loss of data stored within the first solid electrolyte layer 204. In order to avoid this, according to one embodiment of the present invention, the memory state of the first solid electrolyte layer 204 is copied (“mirrored”) to the second solid electrolyte layer 205, i.e., the second solid electrolyte layer 205 adopts the memory state of the first solid electrolyte layer 204.

In order to carry out the copying process, a programming voltage Vₛₜₒᵣₑ is applied between the first electrode layer 201 and the third electrode layer 203, as shown in FIG. 5. The second electrode layer 202 is kept floating when applying the programming voltage Vₛₜₒᵣₑ. If the first conductive path 403 exists within the first solid electrolyte layer 204 (i.e., if the memory state of the first solid electrolyte layer 204 is the ON state having a low resistance), the full programming voltage Vₛₜₒᵣₑ drops across the second solid electrolyte layer 205. As a consequence, the memory state of the second solid electrolyte layer 205 is set to the ON state (i.e., a second conductive path 501 is formed within the second solid electrolyte layer 205). If the first conductive path 403 does not exist, i.e., if the memory state of the first solid electrolyte layer 204 is the OFF state having a high resistance, the voltage drop across the second solid electrolyte layer 205 is only a portion of the programming voltage Vₛₜₒᵣₑ. Therefore, the memory state of the second solid electrolyte layer 205 remains in the OFF state (it is assumed here that the memory state of the second solid electrolyte layer 205 is the OFF state before the programming voltage Vₛₜₒᵣₑ is applied). The following relations are fulfilled during the application of the programming voltage Vₛₜₒᵣₑ between the first electrode layer 201 and the third electrode layer 203, Vₛₜₒᵣₑ>VthON2 and Vₛₜₒᵣₑ<(VthON1+VthON2), wherein VthON1 is the memory state programming threshold voltage of the first solid electrolyte layer 204, and VthON2 is the memory state programming threshold voltage of the second solid electrolyte layer 205.

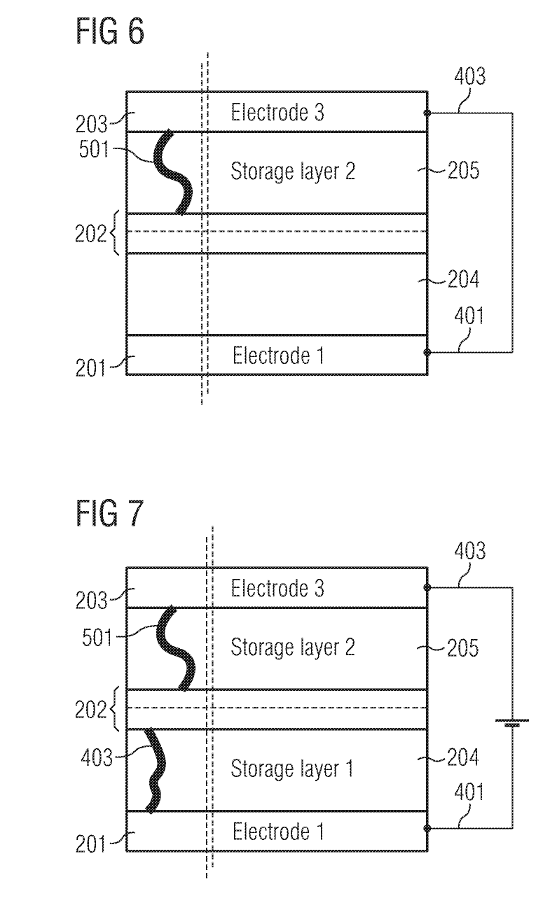

FIG. 6 shows the situation after having switched off the solid electrolyte memory cell 300 shown in FIG. 5 for a period of time being longer than the retention time of the first solid electrolyte layer 204, resulting in a loss of the memory state of the first solid electrolyte layer 204 as shown in FIG. 5. However, due to the high data retention of the second solid electrolyte layer 205, the memory state of the second solid electrolyte layer 205 has been maintained.

Since it is better to operate the solid electrolyte memory cell 300 using the first solid electrolyte layer 205 (high memory state switching speed), it may be desirable to retransfer the memory state of the second solid electrolyte layer 205 back to the first solid electrolyte layer 204. To do this, a programming voltage Vₛₜₒᵣₑ may be applied between the first electrode layer 201 and the third electrode layer 203. The second electrode layer 202 is kept in a floating state during the application of the programming voltage Vₛₜₒᵣₑ. If the memory state of the second solid electrolyte layer 205 is the ON state, as shown in FIG. 6 (low resistance), the full programming voltage Vₛₜₒᵣₑ drops across the first solid electrolyte layer 204. As a consequence, the memory state of the first solid electrolyte layer 204 is set to the ON state, i.e., the first conductive path 403 is restored within the first solid electrolyte layer 204. If the memory state of the second solid electrolyte layer 205 is the OFF state (high resistance), the voltage drop applied across the first solid electrolyte layer 204 is smaller than the programming voltage Vₛₜₒᵣₑ. As a result, the memory state of the first solid electrolyte layer 204 remains in the OFF state.

The following relations are fulfilled during the application of the programming voltage Vₛₜₒᵣₑ between the first electrode layer 201 and the third electrode layer 203: Vₛₜₒᵣₑ>VthON1, and Vₛₜₒᵣₑ<(VthON1+VthON2).

The “loss” of data stored within the first solid electrolyte layer 204 may also result from the fact that a “cleaning” step is performed which sets the memory state of the first solid electrolyte layer 204 to a defined memory state (here the OFF state). This cleaning step increases the reliability of the copying process which copies the memory state of the second solid electrolyte layer 205 to the first solid electrolyte layer 204.

After having carried out the memory state copying process, the situation as shown in FIG. 7 is obtained. In order to increase the reliability of the memory state copying process copying the memory state of the first solid electrolyte layer 204 to the second solid electrolyte layer 205 at a later point of time (for example, before the next switching off of the solid electrolyte memory device comprising the solid electrolyte memory cell 300), a “cleaning” process can be carried out which sets the memory state of the second solid electrolyte layer 205 to a defined memory state (here the OFF state).

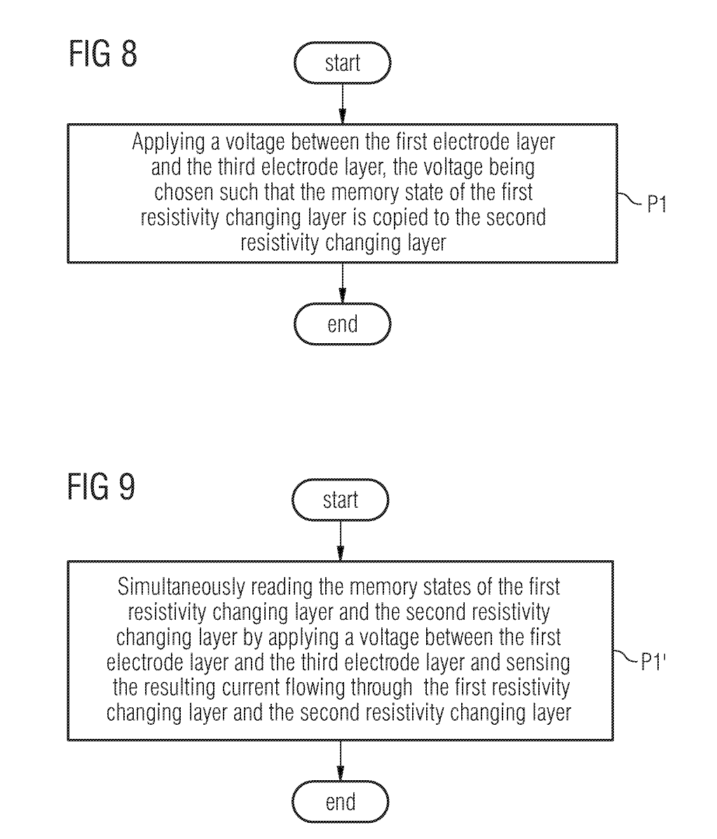

FIG. 8 shows one embodiment of the method of operating the solid electrolyte memory cell 200. In this embodiment, in a process P1, a voltage is applied between the first electrode layer 201 and the third electrode layer 203 of the solid electrolyte memory cell 200, the voltage being chosen such that the memory state of the first solid electrolyte layer 204 is copied to the second solid electrolyte layer 205, or vice versa.

FIG. 9 shows one embodiment of the method of operating the solid electrolyte memory cell 200. In a step P1′, the memory states of the first solid electrolyte layer 204 and the second solid electrolyte layer 205 are read simultaneously by applying a voltage between the first electrode layer 201 and the third electrode layer 203 and sensing the resulting current (or a voltage) flowing through the first solid electrolyte layer 204 and the second solid electrolyte layer 205.

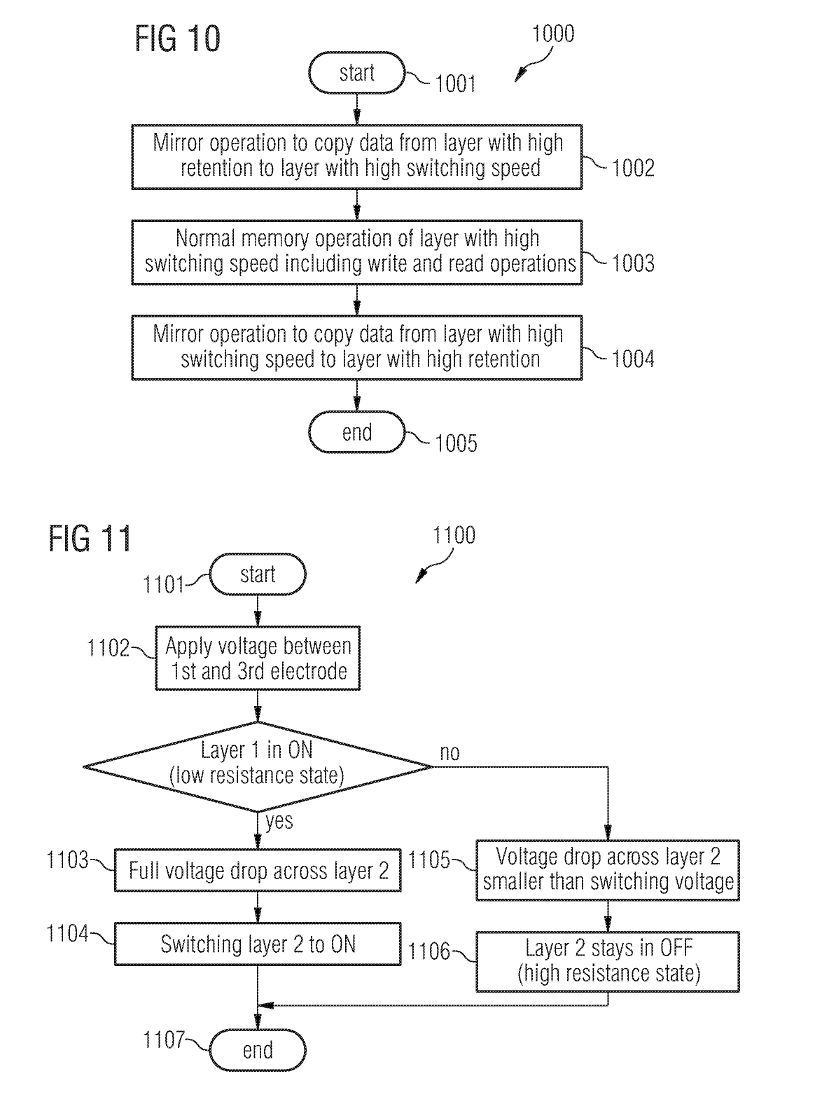

FIG. 10 shows a method 1000 of operating the solid electrolyte memory cell 200 according to one embodiment of the present invention. In a first process 1001, the method is started. In a second process 1002 (for example, during the start up process of a memory device including the memory cell 200), a mirror operation is carried out in which data from a layer with high data retention (for example, the first solid electrolyte layer 204) is copied into a layer with high switching speed (for example, the second solid electrolyte layer 205). In a third process 1003, the solid electrolyte memory cell 200 is operated in the “normal” mode which means that data is read from/written into the layer with the high switching speed. In a fourth process 1004 (for example, during the switch off process of a memory device including the memory cell 200), a mirror operation is carried out in which data is copied from the layer with the high switching speed into the layer with the high data retention. In a fifth process 1005, the method is terminated.

FIG. 11 shows a method 1100 of operating the solid electrolyte memory cell 200 according to one embodiment of the present invention. In a first process 1101, the method is started. In a second process 1102, a voltage is applied between the first electrode layer 201 and the third electrode layer 203. If the first solid electrolyte layer 204 is in the ON state (low resistance state), the full voltage drops across the second solid electrolyte layer 205 (which is assumed to be in an OFF state (high resistance state)) in a third process 1103 which effects that in a fourth process 1104 the second solid electrolyte layer 205 switches from the OFF state to the ON state. If the first solid electrolyte layer 204 is not in the ON state (i.e., in the OFF state), in a fifth process 1105, a voltage drops across the second solid electrolyte layer 205 (which is assumed to be in the OFF state) which is lower than the switching voltage threshold value. This effects that, in a sixth process 1106, the second solid electrolyte layer 205 does not switch from the OFF state to the ON state, but remains in the OFF state. In this way, the memory state is copied from the first solid electrolyte layer 204 (which is assumed to have high switching speed) into the second solid electrolyte layer 205 (which is assumed to have high data retention). In a seventh process 1107, the method is terminated.

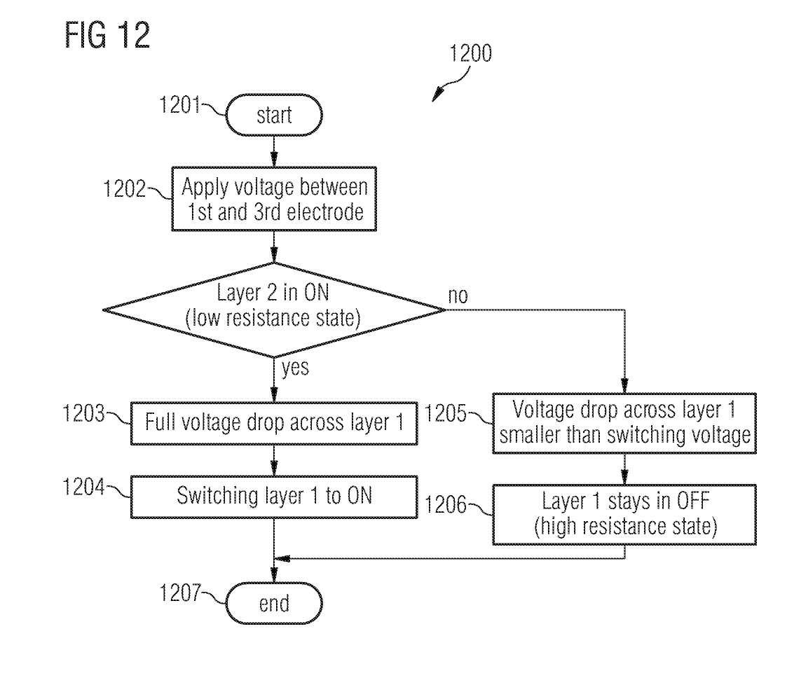

FIG. 12 shows a method 1200 of operating the solid electrolyte memory cell 200 according to one embodiment of the present invention. In a first process 1201, the method is started. In a second process 1202, a voltage is applied between the first electrode layer 201 and the third electrode layer 203. If the second solid electrolyte layer 205 is in the ON state (low resistance state), the full voltage drops across the first solid electrolyte layer 204 (which is assumed to be in an OFF state (high resistance state)) in a third process 1203 which effects that in a fourth process 1204 the first solid electrolyte layer 204 switches from the OFF state to the ON state. If the second solid electrolyte layer 205 is not in the ON state (i.e., in the OFF state), in a fifth process 1205, a voltage drops across the first solid electrolyte layer 204 (which is assumed to be in the OFF state) which is lower than the switching voltage threshold value. This effects that, in a sixth process 1206, the first solid electrolyte layer 204 does not switch from the OFF state to the ON state, but remains in the OFF state. In a seventh process 1207, the method is terminated. In this way, the memory state is copied from the second solid electrolyte layer 205 (which is assumed to have high data retention) into the first solid electrolyte layer 204 (which is assumed to have high switching speed).

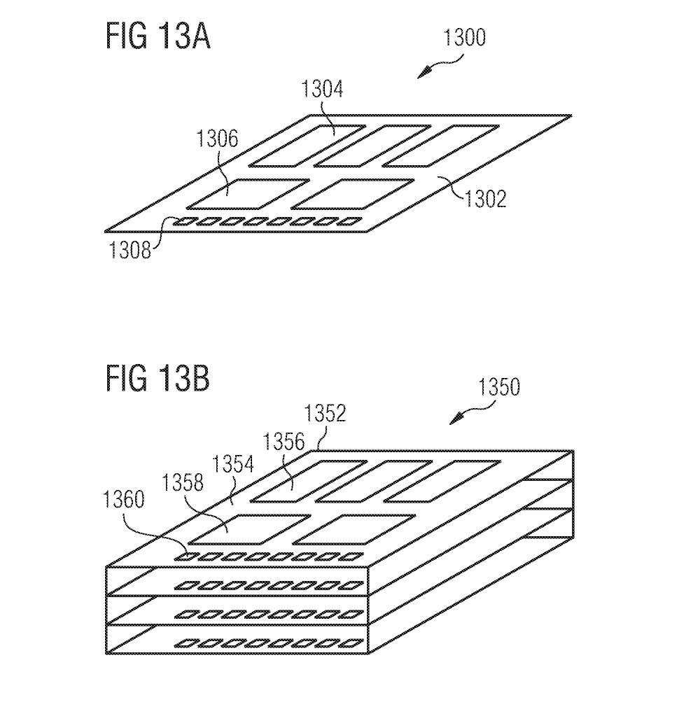

As shown in FIGS. 13A and 13B, in some embodiments, memory devices such as those described herein may be used in modules. In FIG. 13A, a memory module 1300 is shown, on which one or more integrated circuits and/or memory cells 1304 according to one embodiment of the present invention are arranged on a substrate 1302. The memory module 1300 may also include one or more electronic devices 1306, which may include memory, processing circuitry, control circuitry, addressing circuitry, bus interconnection circuitry, or other circuitry or electronic devices that may be combined on a module with a memory device, such as the integrated circuits and/or memory cells 1304. Additionally, the memory module 1300 includes multiple electrical connections 1308, which may be used to connect the memory module 1300 to other electronic components, including other modules. For example, the module 1300 may be plugged into a larger circuit board, including PC main boards, video adapters, cell phone circuit boards or portable video or audio players, among others.

As shown in FIG. 13B, in some embodiments, these modules may be stackable, to form a stack 1350. For example, a stackable memory module 1352 may contain one or more memory devices 1356, arranged on a stackable substrate 1354. The memory device 1356 contains memory cells that employ memory elements in accordance with an embodiment of the invention. The stackable memory module 1352 may also include one or more electronic devices 1358, which may include memory, processing circuitry, control circuitry, addressing circuitry, bus interconnection circuitry, or other circuitry or electronic devices that may be combined on a module with a memory device, such as the memory device 1356. Electrical connections 1360 are used to connect the stackable memory module 1352 with other modules in the stack 1350, or with other electronic devices. Other modules in the stack 1350 may include additional stackable memory modules, similar to the stackable memory module 1352 described above, or other types of stackable modules, such as stackable processing modules, control modules, communication modules, or other modules containing electronic components.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as “crystalline state”, whereas the crystallization state having a low degree of crystallization is also referred to as “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistivity of the resistivity changing memory cell, which represents the memory state of the memory cell.

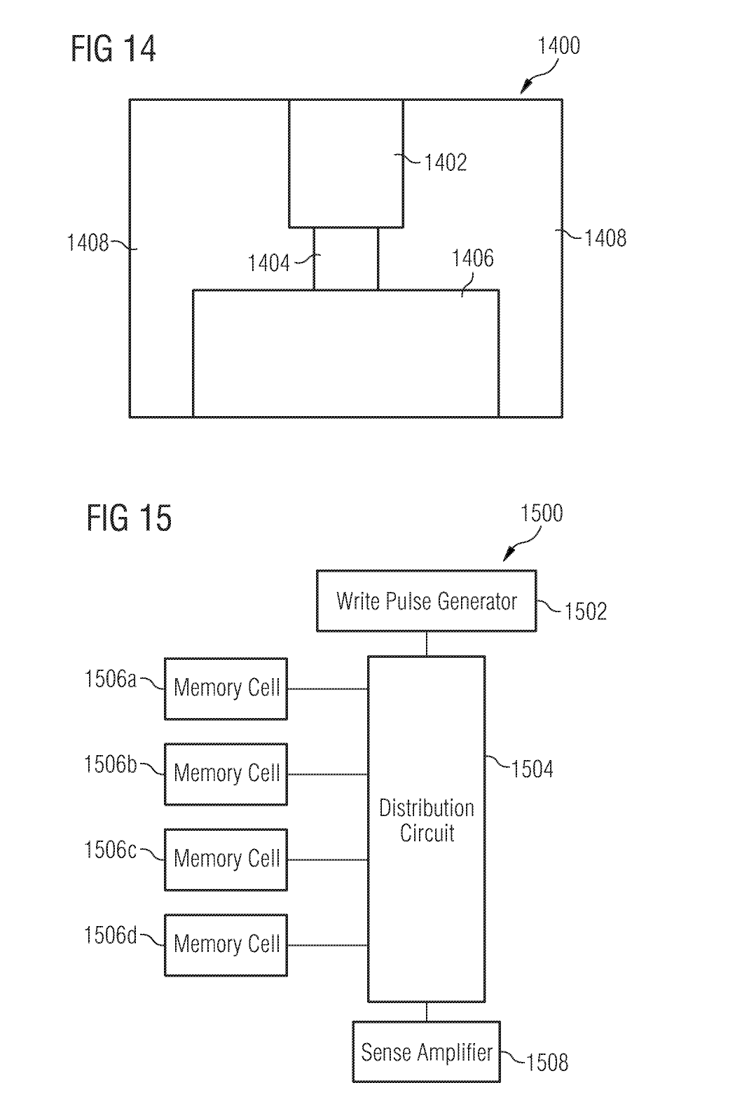

FIG. 14 illustrates a cross-sectional view of an exemplary phase changing memory cell 1400 (active-in-via type). The phase changing memory cell 1400 includes a first electrode 1402, a phase changing material 1404, a second electrode 1406, and an insulating material 1408. The phase changing material 1404 is laterally enclosed by the insulating material 1408. To use the phase changing memory cell, a selection device (not shown), such as a transistor, a diode, or another active device, may be coupled to the first electrode 1402 or to the second electrode 1406 to control the application of a current or a voltage to the phase changing material 1404 via the first electrode 1402 and/or the second electrode 1406. To set the phase changing material 1404 to the crystalline state, a current pulse and/or voltage pulse may be applied to the phase changing material 1404, wherein the pulse parameters are chosen such that the phase changing material 1404 is heated above its crystallization temperature, while keeping the temperature below the melting temperature of the phase changing material 1404. To set the phase changing material 1404 to the amorphous state, a current pulse and/or voltage pulse may be applied to the phase changing material 1404, wherein the pulse parameters are chosen such that the phase changing material 1404 is quickly heated above its melting temperature, and is quickly cooled.

The phase changing material 1404 may include a variety of materials. According to one embodiment, the phase changing material 1404 may include or consist of a chalcogenide alloy that includes one or more elements from group VI of the periodic table. According to another embodiment, the phase changing material 1404 may include or consist of a chalcogenide compound material, such as GeSbTe, SbTe, GeTe or AgInSbTe. According to a further embodiment, the phase changing material 1404 may include or consist of chalcogen free material, such as GeSb, GaSb, InSb, or GeGaInSb. According to still another embodiment, the phase changing material 1404 may include or consist of any suitable material including one or more of the elements Ge, Sb, Te, Ga, Bi, Pb, Sn, Si, P, O, As, In, Se, and S.

According to one embodiment, at least one of the first electrode 1402 and the second electrode 1406 may include or consist of Ti, V, Cr, Zr, Nb, Mo, Hf, Ta, W, or mixtures or alloys thereof. According to another embodiment, at least one of the first electrode 1402 and the second electrode 1406 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 15 illustrates a block diagram of a memory device 1500 including a write pulse generator 1502, a distribution circuit 1504, phase changing memory cells 1506a, 1506b, 1506c, 1506d (for example, phase changing memory cells 200 as shown in FIG. 2), and a sense amplifier 1508. According to one embodiment, the write pulse generator 1502 generates current pulses or voltage pulses that are supplied to the phase changing memory cells 1506a, 1506b, 1506c, 1506d via the distribution circuit 1504, thereby programming the memory states of the phase changing memory cells 1506a, 1506b, 1506c, 1506d. According to one embodiment, the distribution circuit 1504 includes a plurality of transistors that supply direct current pulses or direct voltage pulses to the phase changing memory cells 1506a, 1506b, 1506c, 1506d or to heaters being disposed adjacent to the phase changing memory cells 1506a, 1506b, 1506c, 1506d.

As already indicated, the phase changing material of the phase changing memory cells 1506a, 1506b, 1506c, 1506d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1508 is capable of determining the memory state of one of the phase changing memory cells 1506a, 1506b, 1506c, or 1506d in dependence on the resistance of the phase changing material.

To achieve high memory densities, the phase changing memory cells 1506a, 1506b, 1506c, 1506d may be capable of storing multiple bits of data, i.e., the phase changing material may be programmed to more than two resistance values. For example, if a phase changing memory cell 1506a, 1506b, 1506c, 1506d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 15 may also be applied in a similar manner to other types of resistivity changing memory cells like programmable metallization cells (PMCs), magento-resistive memory cells (e.g., MRAMs), organic memory cells (e.g., ORAMs), or transition oxide memory cells (TMOs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

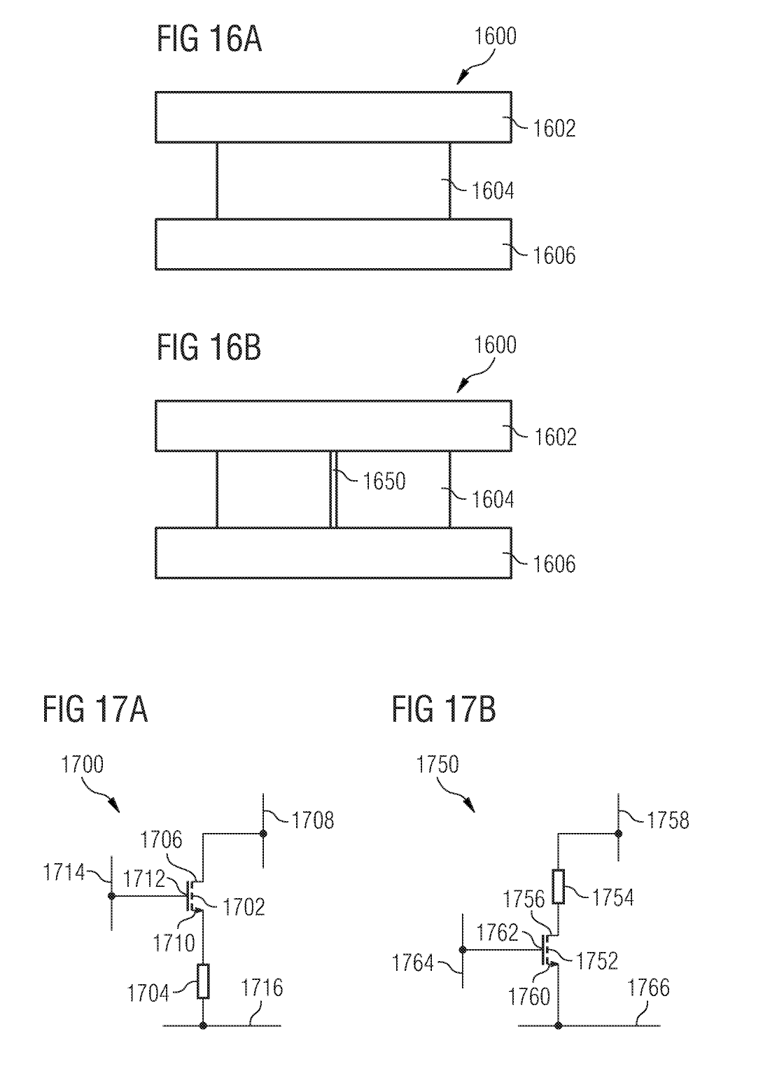

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 16A and 16B.

FIG. 16A shows a carbon memory cell 1600 that includes a top contact 1602, a carbon storage layer 1604 including an insulating amorphous carbon material rich in sp³-hybridized carbon atoms, and a bottom contact 1606. As shown in FIG. 16B, by forcing a current (or voltage) through the carbon storage layer 1604, an sp² filament 1650 can be formed in the sp³-rich carbon storage layer 1604, changing the resistivity of the memory cell. Application of a current (or voltage) pulse with higher energy (or, in some embodiments, reversed polarity) may destroy the sp² filament 1650, increasing the resistance of the carbon storage layer 1604. As discussed above, these changes in the resistance of the carbon storage layer 1604 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 17A shows a schematic representation of such a memory cell that uses a resistivity changing memory element. The memory cell 1700 includes a select transistor 1702 and a resistivity changing memory element 1704. The select transistor 1702 includes a source 1706 that is connected to a bit line 1708, a drain 1710 that is connected to the memory element 1704, and a gate 1712 that is connected to a word line 1714. The resistivity changing memory element 1704 also is connected to a common line 1716, which may be connected to ground, or to other circuitry, such as circuitry (not shown) for determining the resistance of the memory cell 1700, for use in reading. Alternatively, in some configurations, circuitry (not shown) for determining the state of the memory cell 1700 during reading may be connected to the bit line 1708. It should be noted that as used herein the terms connected and coupled are intended to include both direct and indirect connection and coupling, respectively.

To write to the memory cell 1700, the word line 1714 is used to select the memory cell 1700, and a current (or voltage) pulse on the bit line 1708 is applied to the resistivity changing memory element 1704, changing the resistance of the resistivity changing memory element 1704. Similarly, when reading the memory cell 1700, the word line 1714 is used to select the cell 1700, and the bit line 1708 is used to apply a reading voltage (or current) across the resistivity changing memory element 1704 to measure the resistance of the resistivity changing memory element 1704.

The memory cell 1700 may be referred to as a 1T1J cell, because it uses one transistor, and one memory junction (the resistivity changing memory element 1704). Typically, a memory device will include an array of many such cells. It will be understood that other configurations for a 1T1J memory cell, or configurations other than a 1T1J configuration may be used with a resistivity changing memory element. For example, in FIG. 17B, an alternative arrangement for a 1T1J memory cell 1750 is shown, in which a select transistor 1752 and a resistivity changing memory element 1754 have been repositioned with respect to the configuration shown in FIG. 17A. In this alternative configuration, the resistivity changing memory element 1754 is connected to a bit line 1758, and to a source 1756 of the select transistor 1752. A drain 1760 of the select transistor 1752 is connected to a common line 1766, which may be connected to ground, or to other circuitry (not shown), as discussed above. A gate 1762 of the select transistor 1752 is controlled by a word line 1764.

In the following description, further aspects of the present invention will be discussed.

According to one embodiment of the present invention, materials with high retention and materials with high switching speed are provided for resistive memory cells (CBRAM).

Memory cells comprising solid electrolyte material are known as programmable metallization memory cells (PMC memory cells). Memory devices including such PMC memory cells are known as conductive bridging random access memory devices (CBRAM). Storing of different states in a PMC memory cell is based on the resistance change induced by the development or diminishing of a conductive path in the electrolyte material between electrodes.

Memory cells often have a trade-off between switching speed and retention, e.g., materials and technologies with a good retention show a slow switching behavior and vice versa. Some memory devices use DRAM for applications with fast memory access and FLASH for applications where data storage over long periods is required.

According to one embodiment, different approaches are combined in order to achieve fast memory operation and long data retention at the same time:

MCP: multi-chip-package, combining chips with DRAM and chips with FLASH in one package;

different types of chips on one board; and

battery-backed DRAM or SRAM for emulation of data retention during power-off

All these approaches have significant disadvantages like increasing costs (doubling the number of necessary chips), complexity due to controlling chips and operation, malfunction due to empty batteries, and increasing weight of the memory module.

According to one embodiment of the present invention, two storage layers are combined in one memory cell. One storage layer is designed for fast switching speed, the other storage layer for good retention. Both storage layers are stacked and use a common electrode. Possible effects associated with this embodiment are:

no or only small increase in cell size compared to memory devices having different memory cells for each function;

improved design and engineering possibilities to tune each layer for optimum performance;

no or only small increase in complexity compared to memory devices having different memory cells for each function, no additional devices required; and

high-speed and high retention.

According to one embodiment of the present invention, the memory cell comprises a bottom electrode (first electrode, e.g. inert metal W, Ti), a lower storage layer based on solid electrolyte (in this example designed for fast operation, first storage layer, e.g., GeSe), an intermediate metal layer designed as a common electrode (second electrode, Cu, Ag plus inert metal), the upper storage layer based on solid electrolyte (in this example designed for good retention, second storage layer, e.g. GeS) and a top electrode (third electrode, e.g., Ag, Cu). Possible pre- and post-processing steps may be carried out as being done in conjunction with known memory devices (CBRAM).

According to one embodiment of the present invention, a “normal” operation is performed using the first storage layer in between the first electrode and the second electrode. This means that program, erase, and read voltages are applied to these electrodes. The operation can include refresh cycles if necessary (DRAM like). Before power-off or stand-by, the information stored in the first storage layer is mirrored to the second storage layer. This is realized by applying a programming voltage between the first electrode and the third electrode, the second electrode being floating. If, for a given cell the first storage layer is in the ON state (low resistance), the full programming voltage drops over the second storage layer, which in turn is written to the ON state. On the other hand, for all cells with the first storage layer in the OFF state the voltage drop is shared between both storage layers. Setting the programming voltage lower than the sum of the threshold voltages for both storage layers assures that both storage layers remain in the initial OFF state.

According to one embodiment of the present invention, an initial information re-storing process (during power-on) is carried out. To do this, the procedure described above is carried out again in inverse mode. The programming voltage is applied between the first electrode and the third electrode, thus the information from the second storage layer is mirrored to the first storage layer, and normal operation can be started. To delete the information in the second storage layer, the first electrode and the second electrode are connected to the same potential, and the erase voltage is applied between the second electrode and the third electrode.

According to one embodiment of the present invention, depending on the application needs, different modes of operation may be realized:

High speed and low retention: Full DRAM like operation with refresh cycles for the first storage layer and mirroring before power off/stand by; and

Medium speed and/or low power: first storage layer without refresh cycles, mirror the information into the second storage layer after elapsed retention time for the first storage layer.

As used herein the terms “connected” and “coupled” are intended to include both direct and indirect connection and coupling, respectively.

According to one embodiment of the present invention, memory devices having both high memory state switching speed characteristics and high data retention characteristics are provided.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. An integrated circuit comprising a memory cell comprising at least two resistivity changing layers that are stacked above each other, each resistivity changing layer serving as a separate data storage layer and having individual data storing properties.

2. The integrated circuit according to claim 1, wherein each resistivity changing layer has individual data retention properties or data writing properties.

3. The integrated circuit according to claim 1, wherein the resistivity changing layers are grouped into pairs, the resistivity changing layers of a pair being disposed adjacent to each other and being electrically connected by an electrical connection.

4. The integrated circuit according to claim 3, wherein the electrical connection comprises a common electrode layer.

5. The integrated circuit according to claim 1, further comprising:
a first electrode layer, a second electrode layer, and a third electrode layer, the second electrode layer being provided between the first electrode layer and the third electrode layer;
a first resistivity changing layer provided between the first electrode layer and the second electrode layer; and
a second resistivity changing layer provided between the second electrode layer and the third electrode layer.

6. The integrated circuit according to claim 5, wherein the first resistivity changing layer has a higher memory state switching speed than the second resistivity changing layer.

7. The integrated circuit according to claim 5, wherein the second resistivity changing layer has a higher data retention than the first resistivity changing layer.

8. The integrated circuit according to claim 5, wherein the first resistivity changing layer comprises GeS, AgS or a combination of these materials or consists of GeS, AgS or a combination of these materials.

9. The integrated circuit according to claim 5, wherein the second resistivity changing layer comprises GeSe, AgSe or a combination of these materials, or consists of GeSe, AgSe or a combination of these materials.

10. The integrated circuit according to claim 5, wherein the first electrode layer comprises inert material or consists of inert material.

11. The integrated circuit according to claim 5, wherein the second electrode layer comprises inert material and reactive material.

12. The integrated circuit according to claim 5, wherein the third electrode layer comprises reactive material or consists of reactive material.

13. The integrated circuit according to claim 5, wherein the second electrode comprises a first portion arranged on the first resistivity changing layer, and a second portion arranged on the first portion, the first portion comprises reactive material or consists of reactive material, and the second portion comprises inert material or consists of inert material.

14. The integrated circuit according to claim 10, wherein the inert material comprises Ti, W, TiN, WN, Ta or a combination of these materials, or consists of Ti, W, TiN, WN, Ta or a combination of these materials.

15. The integrated circuit according to claim 10, wherein the reactive material comprises Cu, Ag or other metallic material, or consists of Cu, Ag or other metallic material.

16. The integrated circuit according to claim 5, wherein the thickness of the first electrode layer or of the second portion of the second electrode layer ranges from 2 nm to 10 μm.

17. The integrated circuit according to claim 5, wherein thickness of the first resistivity changing layer or of the second resistivity changing layer ranges from 2 nm to 2 μm.

18. The integrated circuit according to claim 5, wherein the thickness of the first portion of the second electrode layer or of the third electrode layer is lower than 100 nm.

19. The integrated circuit according to claim 5, wherein each of the first electrode layer, the second electrode layer or the third electrode layer are individually addressable via respective electrode layer terminals.

20. The integrated circuit according to claim 5, wherein the first electrode layer is a bottom electrode layer of the first resistivity changing layer, the second electrode layer is a top electrode layer of the first resistivity changing layer and the bottom electrode layer of the second resistivity changing layer, and the third electrode layer is a top electrode layer of the second resistivity changing layer.

21. A memory cell comprising at least two resistivity changing layers stacked above each other, wherein each resistivity changing layer serves as a separate data storage layer and has individual data storing properties.

22. A memory cell array comprising a plurality of memory cells, wherein each memory cell comprises at least two resistivity changing layers stacked above each other, each resistivity changing layer serving as a separate data storage layer and having individual data storing properties.

23. The memory cell array according to claim 22, each memory cell further comprising:
a first electrode layer, a second electrode layer, and a third electrode layer, the second electrode layer provided between the first electrode layer and the third electrode layer;
a first resistivity changing layer provided between the first electrode layer and the second electrode layer; and
a second resistivity changing layer provided between the second electrode layer and the third electrode layer.

24. A method of operating an integrated circuit comprising a memory cell, the memory cell comprising:
a first electrode layer, a second electrode layer, and a third electrode layer, the second electrode layer provided between the first electrode layer and the third electrode layer;
a first resistivity changing layer provided between the first electrode layer and the second electrode layer; and
a second resistivity changing layer provided between the second electrode layer and the third electrode layer; the method comprising:
applying a voltage between the first electrode layer and the third electrode layer, the voltage chosen such that a memory state of the first resistivity changing layer is copied to the second resistivity changing layer.

25. The method according to claim 24, wherein the first resistivity changing layer enables the storage of data with high data storage speed, the second resistivity changing layer enables the storage of data with high data retention.

26. The method according to claim 24, wherein the second electrode layer is kept in a floating state during the application of the voltage between the first electrode and the third electrode.

27. The method according to claim 24, wherein the following relations are fulfilled during application of the voltage between the first electrode layer and the third electrode layer:
Vₛₜₒᵣₑ>VthON2, and Vₛₜₒᵣₑ<(VthON1+VthON2);
Vₛₜₒᵣₑ being the voltage applied between the first electrode and the third electrode;
VthON1 being the memory state programming threshold voltage of the first resistivity changing layer; and
VthON2 being the memory state programming threshold voltage of the second resistivity changing layer.

28. The method according to claim 24, further comprising setting the memory state of the second resistivity changing layer to a defined memory state before copying the memory state of the first resistivity changing layer to the second resistivity changing layer.

29. The method according to claim 24, comprising applying a voltage between the first electrode layer and the third electrode layer, the voltage chosen such that the memory state of the second resistivity changing layer is copied into the first resistivity changing layer.

30. The method according to claim 29, wherein the second electrode layer is kept in a floating state during application of a voltage between the first electrode and the third electrode.

31. The method according to claim 29, wherein the following relations are fulfilled during application of the voltage between the first electrode layer and the third electrode layer:
Vₛₜₒᵣₑ>VthON1, and Vₛₜₒᵣₑ<(VthON1+VthON2);
Vₛₜₒᵣₑ being the voltage applied between the first electrode and the third electrode;
VthON1 being the memory state programming threshold voltage of the first resistivity changing layer; and
VthON2 being the memory state programming threshold voltage of the second resistivity changing layer.

32. The method according to claim 29, further comprising the process of setting the memory state of the first resistivity changing layer to a defined memory state before copying the memory state of the second resistivity changing layer into the first resistivity changing layer.

33. A method of operating an integrated circuit comprising a memory cell, the memory cell comprising:
a first electrode layer, a second electrode layer, and a third electrode layer, the second electrode layer being provided between the first electrode layer and the third electrode layer;
a first resistivity changing layer provided between the first electrode layer and the second electrode layer; and
a second resistivity changing layer provided between the second electrode layer and the third electrode layer;
the method comprising:
simultaneously reading memory states of the first resistivity changing layer and the second resistivity changing layer by applying a voltage between the first electrode layer and the third electrode layer and sensing the resulting current flowing through the first resistivity changing layer and the second resistivity changing layer.

34. A method of operating a memory cell, the memory cell comprising:
a first electrode layer, a second electrode layer, and a third electrode layer, the second electrode layer provided between the first electrode layer and the third electrode layer;
a first resistivity changing layer provided between the first electrode layer and the second electrode layer; and
a second resistivity changing layer provided between the second electrode layer and the third electrode layer;
the method comprising:
simultaneously reading memory states of the first resistivity changing layer and the second resistivity changing layer by applying a voltage between the first electrode layer and the third electrode layer and sensing the resulting current flowing through the first resistivity changing layer and the second resistivity changing layer.

35. A method of operating a memory cell, the memory cell comprising:
a first electrode layer, a second electrode layer, and a third electrode layer, the second electrode layer being provided between the first electrode layer and the third electrode layer;
a first resistivity changing layer being provided between the first electrode layer and the second electrode layer; and
a second resistivity changing layer provided between the second electrode layer and the third electrode layer;
the method comprising:
applying a voltage between the first electrode layer and the third electrode layer, the voltage being chosen such that a memory state of the first resistivity changing layer is copied to the second resistivity changing layer.

36. A method of fabricating a memory cell, comprising:
providing a first electrode layer;
providing a first resistivity changing layer on the first electrode layer;
providing a second electrode layer on the first resistivity changing layer;
providing a second resistivity changing layer on the second electrode layer; and
providing a third electrode layer on the second resistivity changing layer.

37. A memory module comprising at least one integrated circuit comprising a memory cell comprising at least two resistivity changing layers being stacked above each other, each resistivity changing layer serving as a separate data storage layer and having individual data storing properties.

38. The memory module according to claim 37, wherein the memory module is stackable.
